(19) United States
(12) Patent Application Publication
(10) Pub. No.: US 2026/0259256 A1
(43) Pub. Date: Sep. 3, 2026

(54) CARRIER, INSPECTION SYSTEM, AND INSPECTION METHOD

(71) Applicant: Tokyo Electron Limited, Tokyo (JP)

(72) Inventor: Takeo MIURA, Tokyo (JP)

(21) Appl. No.: 19/543,233

(22) Filed: Feb. 18, 2026

Related U.S. Application Data
(60) Provisional application No. 63/764,668, filed on Feb. 28, 2025.

(30) Foreign Application Priority Data
Jan. 30, 2026 (JP) 2026-014615

(51) Int. Cl. G01R 31/28

(52) U.S. Cl. CPC G01R 31/2867; G01R 31/2831; G01R 31/2863; G01R 31/2868; G01R 31/2875; G01R 31/2879

(57) ABSTRACT

A carrier is provided which is configured to collectively support a plurality of electronic devices that are divided. The carrier includes a base having a flat-plate shape; and a plurality of base dies that are disposed on one surface of the base and to which a plurality of electronic devices are to be separably fixed. The base and the plurality of base dies include a material including at least one of silicon or carbon.

### CROSS-REFERENCE TO RELATED APPLICATIONS

This application is based upon and claims priority to U.S. Provisional Patent Application No. 63/764,668, filed on Feb. 28, 2025, and Japanese Patent Application No. 2026-014615, filed on Jan. 30, 2026, the entire contents of which are incorporated herein by reference.

### BACKGROUND

### Field of the Invention

The present disclosure relates to a carrier, an inspection system, and an inspection method.

### Description of the Related Art

Japanese Laid-Open Patent Application Publication No. 2012-122847 discloses an inspection system (characteristics measurement system) that inspects a plurality of divided (fragmented) electronic devices (semiconductor chips). This inspection system performs inspection in a state in which each electronic device is attached to a dicing tape fixed to a film frame. Specifically, the inspection system images each electronic device on the dicing tape with a camera, drives a drive mechanism in accordance with the recognized position to align the electronic devices, and then performs inspection by contacting each probe with each electronic device.

### SUMMARY

According to an aspect of the present disclosure, a carrier is provided which is configured to collectively support a plurality of electronic devices that are divided. The carrier includes: a base having a flat-plate shape; and a plurality of base dies that are disposed on one surface of the base and to which a plurality of electronic devices are separably fixed. The base and the plurality of base dies include a material including at least one of silicon or carbon.

### BRIEF DESCRIPTION OF THE DRAWINGS

FIG. 1A is a flowchart illustrating a process flow of an inspection method according to an embodiment of the present disclosure.

FIG. 1B is a flowchart illustrating a process flow of an inspection method according to a comparative example.

FIG. 2A is a vertical cross-sectional diagram schematically illustrating a portion of a device support according to an embodiment of the present disclosure.

FIG. 2B is a vertical cross-sectional diagram schematically illustrating a portion of a device support according to a modified example.

FIG. 3A is an enlarged perspective diagram of a base die.

FIG. 3B is a perspective diagram illustrating a state in which base dies are disposed on a base wafer.

FIG. 4 is a plan diagram illustrating a relationship of arrangement of each electronic device and each base die on the device support.

FIG. 5 is a schematic diagram illustrating a process flow of an inspection method using the device support.

FIG. 6 is a partial cross-sectional diagram schematically illustrating an inspection state of an inspection system according to a second embodiment of the present disclosure.

FIG. 7 is a partial cross-sectional diagram schematically illustrating an inspection state of an inspection system according to a third embodiment of the present disclosure.

FIG. 8 is a partial cross-sectional diagram schematically illustrating an inspection state of an inspection system according to a fourth embodiment of the present disclosure.

FIG. 9 is a partial cross-sectional diagram schematically illustrating an inspection state of an inspection system according to a fifth embodiment of the present disclosure.

FIG. 10 is a partial cross-sectional diagram schematically illustrating an inspection state of an inspection system according to a sixth embodiment of the present disclosure.

FIG. 11 is a partial cross-sectional diagram schematically illustrating an inspection state of an inspection system according to a seventh embodiment of the present disclosure.

FIG. 12 is a partial cross-sectional diagram schematically illustrating an inspection state of an inspection system according to an eighth embodiment of the present disclosure.

FIG. 13A is a partial cross-sectional diagram schematically illustrating an inspection state of an inspection system according to a ninth embodiment of the present disclosure.

FIG. 13B is a perspective diagram illustrating positioning of a carrier and a stage.

FIG. 14A is a plan diagram illustrating a portion of a base wafer and each base die according to the modified example.

FIG. 14B is a plan diagram illustrating the base wafer according to the modified example.

### DETAILED DESCRIPTION OF THE DISCLOSURE

The present disclosure provides a technique that can stably fix a plurality of divided electronic devices.

Hereinafter, embodiments of the present disclosure will be described with reference to the drawings. In the drawings, the same components are denoted by the same reference signs, and duplicate descriptions thereof may be omitted.

In semiconductor production, for example, substrate processing is performed on a disk-shaped wafer to produce a plurality of electronic devices on the wafer. The wafer serving as a base material may be a silicon semiconductor or another compound semiconductor. Further, in semiconductor production, each electronic device formed on the wafer is diced to form divided (fragmented) electronic devices. Each electronic device is mounted in an electronic circuit along with other devices, and electrically driven in the electronic circuit.

One example of an electronic device produced through the above-described production process is a DRAM (Dynamic Random Access Memory), which is a volatile semiconductor memory. The following embodiments will be described taking as an example an HBM (High Bandwidth Memory), among DRAMs, in which a plurality of DRAM dies (device dies) are stacked through 3D stacking. The plurality of DRAM dies are formed into an electronic device including an electrode pad or a bump by being stacked on a logic wafer on which cores having appropriate interconnects are mounted or stacked. The HBM formed in this manner can have a high data transfer rate (bandwidth). The electronic device according to the embodiments is not limited to the HBM, and can be various elements applied to an electronic circuit.

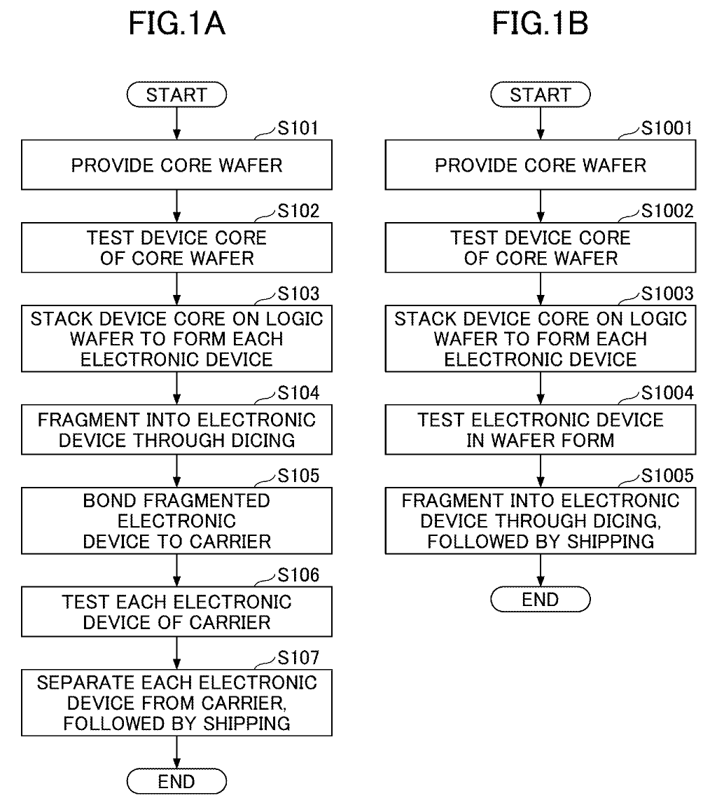

FIG. 1A is a flowchart illustrating a process flow of an inspection method according to an embodiment of the present disclosure. FIG. 1B is a flowchart illustrating a process flow of an inspection method according to a comparative example. The inspection method according to the embodiment is a method of inspecting electrical characteristics including a normal/abnormal state of the above electronic device, and includes a plurality of testing steps performed in a production process of the electronic device. In the following, for facilitating understanding of the inspection method according to the embodiment, the inspection method according to the comparative example illustrated in FIG. 1B will be described first. The inspection method according to the comparative example is conventionally performed in the production process of the DRAM (HBM) electronic device.

The inspection method according to the comparative example first performs a step of providing a core wafer (step S1001). The provided core wafer includes a plurality of device cores (DRAM cores) formed through previous substrate processing, which are fundamental portions of electronic devices. The substrate processing performed on the core wafer includes film formation, etching, ashing, and the like. The core wafer is a disk-shaped product on which device cores are disposed in an undivided state.

Next, the inspection method according to the comparative example performs a step of testing each device core in the form of a core wafer (step S1002). In the testing of the core wafer, a plurality of probes of a probe card are contacted with an electrode pad or bump of each device core using an inspection apparatus (not shown), thereby performing electrical inspection by a tester connected to the probe card. For example, the inspection apparatus performs a burn-in test including continuously supplying a predetermined electrical signal to each device core, a behavior test including changing the temperature of each device core, or the like, thereby determining whether each device core is normal or abnormal.

Subsequently, the core wafer is diced to be fragmented into a plurality of device cores, and then the fragmented device cores are stacked on a logic wafer (step S1003). For example, a plurality of logic dies configured to receive a plurality of device cores are previously provided on a logic wafer. Each logic die incudes an electrode, a bump, and a logic circuit (interconnects) connected to these. A plurality of device cores are stacked on this logic die, thereby forming an electronic device. Because the logic wafer is subjected to logic inspection using another inspection apparatus (not shown) before stacking of each device core, non-defective device cores can be stacked on normal logic dies. However, in the production process including stacking the device cores, transfer of a wafer, molding, back polishing, and the like need to be performed. These steps of the production process apply a mechanical or chemical stress to the device cores. The mechanical stress includes a stress due to handling or heat during stacking. The chemical stress includes, for example, reaction with a processing liquid used for cleaning in the production process or a processing liquid applied in the production process.

Therefore, the inspection method according to the comparative example performs a step of testing each electronic device formed in the above-described manner, while maintaining the form of a wafer (step S1004). The testing of each electronic device includes a burn-in test, a behavior test including changing the temperature, a data transfer test, or the like.

After the testing of each electronic device, the inspection method according to the comparative example performs a step of dicing the logic wafer, and providing (shipping) the fragmented electronic devices (step S1005). The provided electronic devices are, for example, mounted on an electronic circuit (e.g., an insulating substrate) including an expensive chip, such as a GPU (Graphics Processing Unit). That is, each electronic device diced after the testing of the logic wafer is assembled to an actual electronic circuit as is.

During the fragmentation of the wafer through dicing, a mechanical or chemical stress is applied to the electronic devices formed on the wafer in the above-described manner. Therefore, for example, the device cores determined to be non-defective in the state of the core wafer can be defective products in the subsequent production process. If a defective electronic device is assembled to an electronic circuit of a GPU, there is a possibility that the defective electronic device needs to be disposed of along with the GPU, which is a high-end device.

Therefore, for the inspection of the electronic device, it is desirable to test the electronic device after fragmentation through dicing (after application of the stress) yet before mounting on the electronic circuit. However, if each electronic device is attached to a dicing tape for inspection, there are problems that each electronic device is likely to be displaced due to a change in stress of the tape, and that it is difficult to accurately perform temperature adjustment.

Therefore, in the inspection method according to the embodiment, each fragmented electronic device is fixed to a flat plate-shaped carrier to form a device support, and is inspected while in a state of being mounted on the device support. In the following, the inspection method according to the embodiment will be described in detail with reference to FIG. 1A.

In the inspection method according to the embodiment, steps S101 to S103 perform processing in the same manner as in steps S1001 to S1003 of the inspection method according to the comparative example. Therefore, descriptions of steps S101 to S103 will be omitted.

In step S104, the inspection method according to the embodiment dices a logic wafer including a plurality of electronic devices, thereby dividing (fragmenting) the logic wafer into a plurality of electronic devices. That is, each fragmented electronic device is formed without testing each electronic device in the form of a logic wafer, unlike in the inspection method according to the comparative example. Each diced electronic device has a stacked structure including a logic die and a plurality of device cores stacked on the logic die. However, in the inspection method according to the embodiment, testing may be performed in the form of a wafer, i.e., before dicing of a logic wafer. Thus, it is possible to previously determine whether each electronic device is a non-defective electronic device or a defective electronic device on the logic wafer, thereby eliminating the defective electronic device.

Next, the inspection method according to the embodiment performs a step of fixing each fragmented electronic device to a carrier to form a device support (step S105). The carrier is a support substrate configured to separably fix each fragmented electronic device, and to allow each electronic device to be immovable in a fixed state. The structure of the device support including this carrier will be described below in detail.

The inspection method according to the embodiment performs a step of testing each electronic device while in a state of being mounted on the device support formed in step S105 (step S106). In this testing of each electronic device, a typical inspection apparatus configured to inspect a wafer can be used. Therefore, the inspection method according to the embodiment does not need to introduce a dedicated inspection apparatus configured to inspect each fragmented electronic device.

After step S106, the inspection method according to the embodiment separates each electronic device from the carrier, and provides an electronic device determined to be a non-defective product (step S107). The provided electronic device is, for example, assembled to an electronic circuit including a GPU, as described above. This electronic device is determined to be a non-defective product in the testing after fragmentation through dicing, i.e., this electronic device is a device that was not defective due to mechanical stress or the like during dicing. Mounting this electronic device on an electronic circuit including a GPU greatly reduces disposal due to a failure of the electronic device after assembly.

### First Embodiment

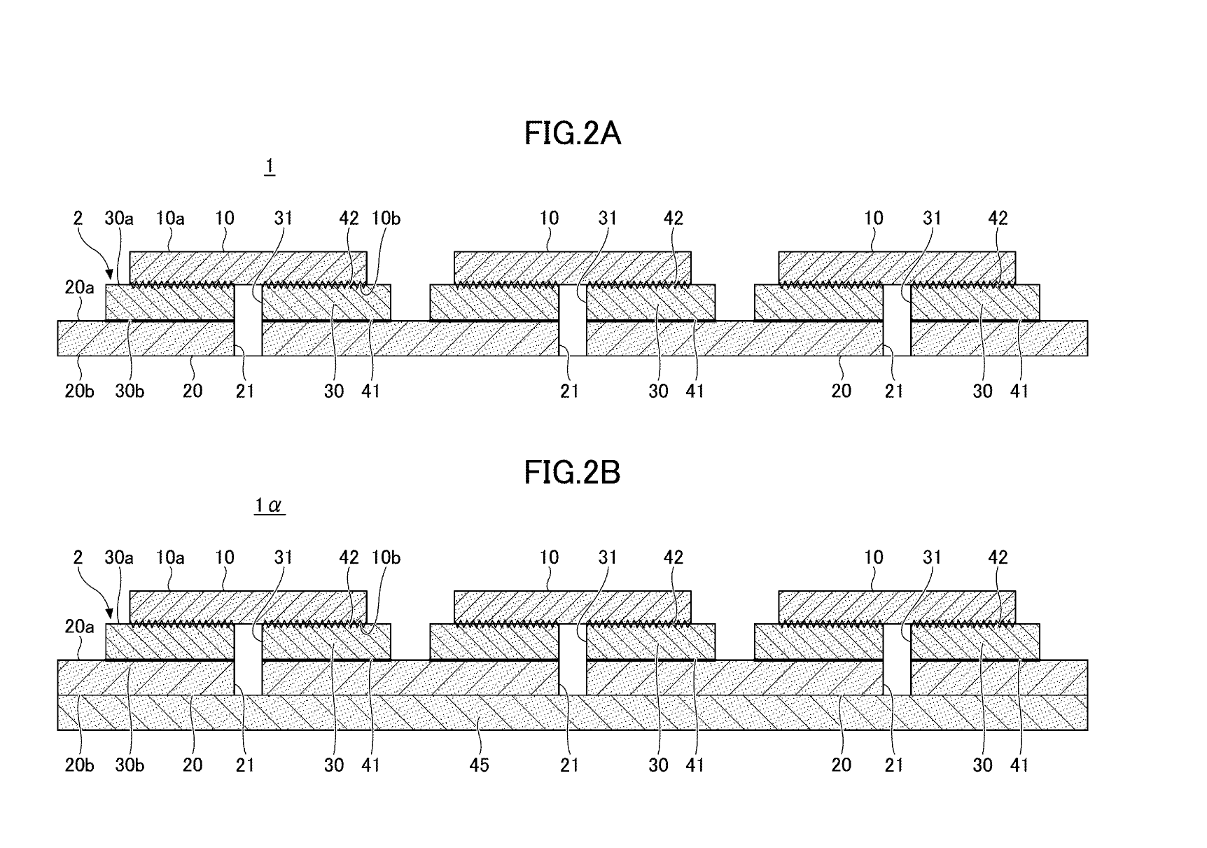

Next, a configuration of a carrier 2 (device support 1), according to a first embodiment of the present disclosure, configured to support each electronic device 10 described above will be described in detail with reference to FIG. 2A. FIG. 2A is a vertical cross-sectional diagram schematically illustrating a portion of the device support 1 according to the embodiment of the present disclosure. FIG. 2B is a vertical cross-sectional diagram schematically illustrating a portion of a device support 1α according to a modified example.

The device support 1 enables inspection of each electronic device 10 by fixing a plurality of electronic devices 10, such as a DRAM (HBM) or the like, to the hard carrier 2. The device support 1 according to the embodiment is a wafer having a disk shape (a regular circle in a plan view). However, no particular limitation is imposed on the shape of the device support 1, and the device support 1 may be formed, for example, in a rectangular shape (square or rectangle) or another polygonal shape in a plan view.

The carrier 2 includes a base wafer 20, and a plurality of base dies 30 bonded to the base wafer 20 and configured to individually support each electronic device 10. The electronic device 10 fixed to the carrier 2 is formed by stacking a plurality of device cores on a logic die as described above. The electronic device 10 includes a first surface 10a facing vertically upward opposite to the carrier 2, and a second surface 10b formed opposite to the first surface 10a.

The electronic device 10 includes a logic die disposed on the first surface 10a side, and a device core disposed on the second surface 10b side. Therefore, the first surface 10a includes an electrode pad or bump that can be contacted by each probe of a probe card of an inspection apparatus (not shown). The second surface 10b is a surface bonded to the base dies 30 of the carrier 2.

The base wafer 20 of the carrier 2 forms a flat plate-shaped base configured to collectively support the base dies 30. Although the base wafer 20 according to the first embodiment is formed in a disk shape, the base wafer 20 may be formed in a rectangular shape (square or rectangle) or another polygonal shape as described above. No particular limitation is imposed on the diameter of the base wafer 20, and the diameter of the base wafer 20 may be set, for example, to about 300 millimeters (mm), similar to a typical wafer. By coinciding the diameter of the base wafer 20 to that of a typical wafer, the carrier 2 can be accurately transferred using a conventional transfer device.

The base wafer 20 extends in a plane direction with a substantially constant thickness. The base wafer 20 has a rigidity sufficient for maintaining the extended posture even if the plurality of base dies 30 and the plurality of electronic devices10 are mounted on the base wafer 20. For example, the thickness of the base wafer 20 may be formed to be larger than the thickness of the electronic device 10, or may be formed to be smaller than the thickness of the electronic device 10.

The base wafer 20 includes a first surface 20a (one surface) to which the plurality of base dies 30 are to be bonded, and a second surface 20b (the other surface) opposite to the first surface 20a. The base wafer 20 includes a through-hole 21 at a bonding site of each base die 30 in the base wafer 20, and the through-hole 21 penetrates through the first surface 20a and the second surface 20b. The diameter of the through-hole 21 is set in a range, for example, of about 0.5 mm or more and 2 mm or less. When each through-hole 21 is formed to have a small diameter in this manner, it is possible to avoid a great reduction in the mechanical strength of the base wafer 20.

The base wafer 20 is preferably formed of a hard material having a low thermal expansion coefficient and a high thermal conductivity. Specific examples of the material of the base wafer 20 include a material containing silicon (Si), a material containing carbon (C), and a material containing silicon (Si) and carbon (C). For example, the base wafer 20 may be a silicon semiconductor substrate or the like. Alternatively, the base wafer 20 may be formed of silicon carbide, quartz glass, industrial diamond, or the like.

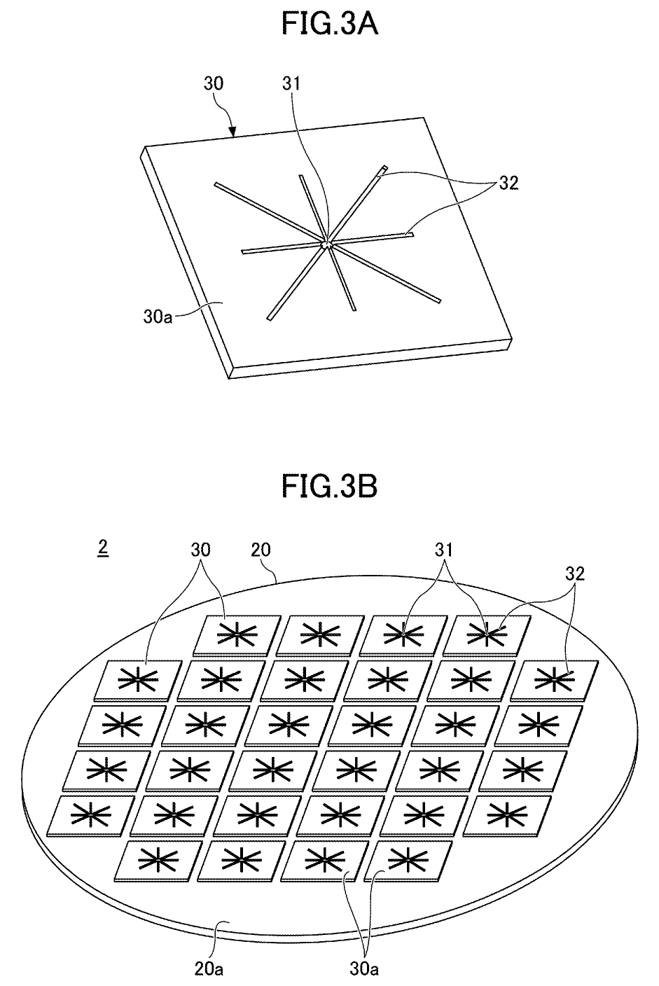

The base die 30 forms a base, on the base wafer 20, configured to directly support the electronic device 10. Each base die 30 is formed in a rectangular shape (square or rectangle) corresponding to the planar shape of the electronic device 10 supported (see FIG. 3A). Each base die 30 has an area larger than the area of the electronic device 10 in a plan view.

Each base die 30 includes a first surface 30a to which the electronic device 10 is to be fixed, and a second surface 30b to be fixed to the base wafer 20 opposite to the first surface 30a. For example, the thickness of each base die 30 may be set to be larger than the thickness of the electronic device 10 and smaller or larger than the thickness of the base wafer 20.

Each base die 30 includes a through-hole 31 penetrating through the first surface 30a and the second surface 30b. For example, the through-hole 31 is formed at the center of the base die 30. The diameter of the through-hole 31 is set to be substantially the same as the diameter of the through-hole 21 of the base wafer 20. Each base die 30 is fixed to the base wafer 20 such that the through-hole 31 overlaps with (communicates with) the through-hole 21.

The base die 30 may be formed of a hard material having a low thermal expansion coefficient and a high thermal conductivity. Specific examples of the material of the base die 30 include a material containing silicon, a material containing carbon, and a material containing silicon and carbon. The material of the base die 30 may be the same as the material of the base wafer 20, or may be a material different from the material of the base wafer 20. When the base wafer 20 and the base die 30 are formed of the same material, the thermal expansion coefficients of the base wafer 20 and the base die 30 can be the same. Therefore, it is possible to suppress, for example, displacement of each base die 30 relative to the base wafer 20 at the time of increasing the temperature. When the material of the base die 30 is the same as that of the base wafer 20, the carrier 2 may be provided (produced) in the form in which the base wafer 20 and each base die 30 are integrally formed in advance.

When the base wafer 20 and each base die 30 are members different from each other, a first bonding layer 41 for firmly fixing the base wafer 20 and each base die 30 to each other is provided between the base wafer 20 and each base die 30. The first bonding layer 41 can fix the base wafer 20 and each base die 30 to each other by means of adhesion, welding, diffusion bonding, or the like. For example, when adhesion between the base wafer 20 and each base die 30 is performed, a thermosetting resin may be used. In this case, by applying an adhesive to the second surface 30b of each base die 30 and then disposing each base die 30 on the base wafer 20, followed by annealing, it is possible to firmly fix each base die 30 to the base wafer 20.

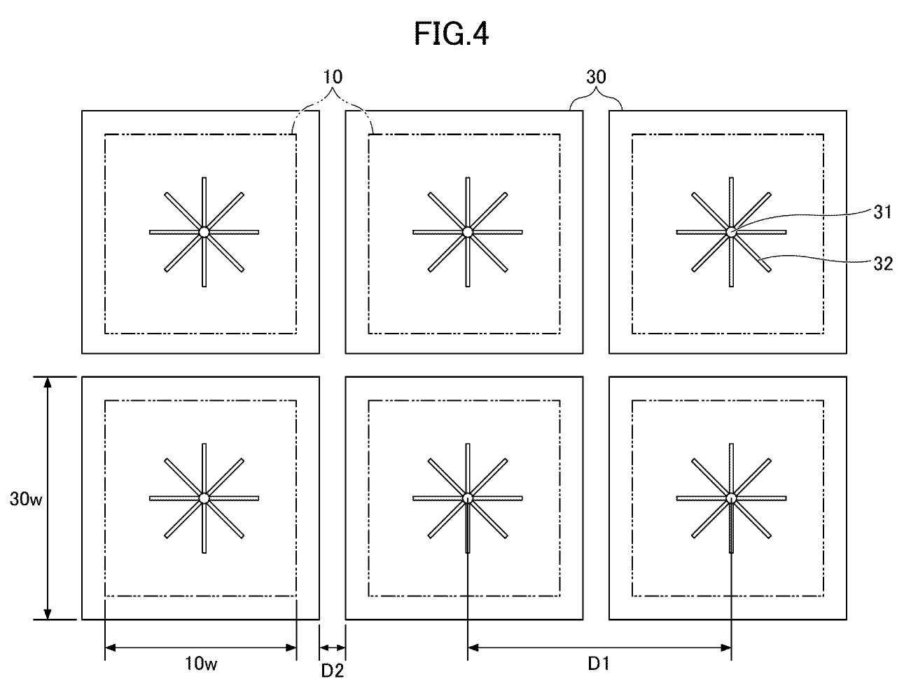

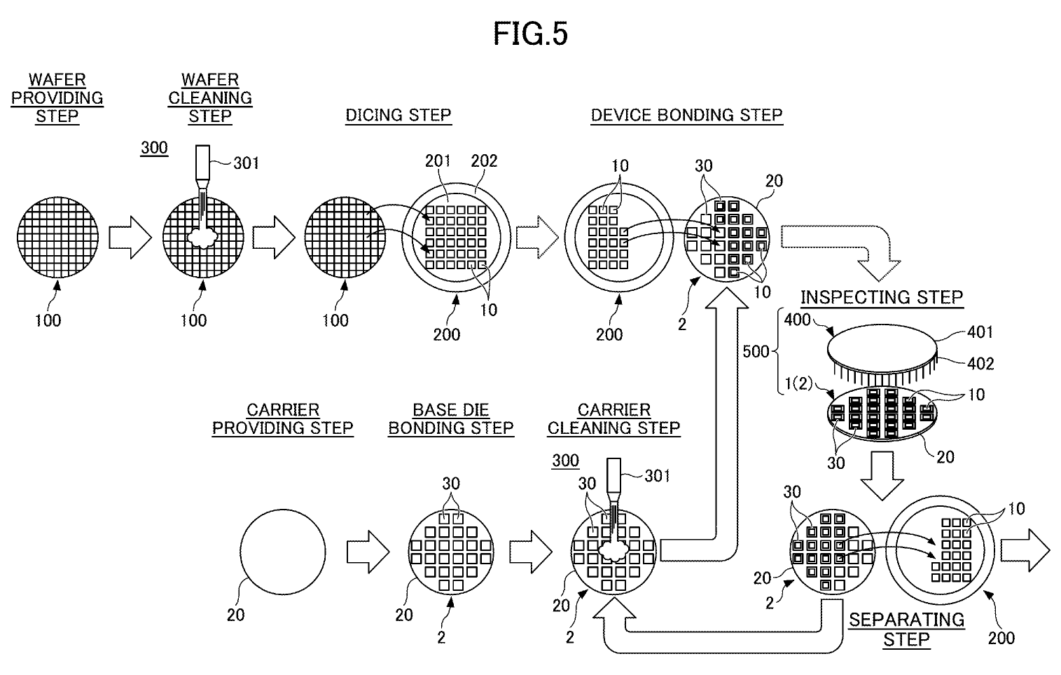

FIG. 3A is an enlarged perspective diagram of the base die 30. FIG. 3B is a perspective diagram illustrating a state in which the base dies 32 are disposed on the base wafer 20. FIG. 4 is a plan diagram illustrating a relationship of arrangement of each electronic device 10 and each base die 30 on the device support 1. In FIG. 3B, each base die 30 is enlarged for ease of understanding. Each actual base die 30 is formed sufficiently small in accordance with the size of each electronic device 10, and is disposed on the base wafer 20 in a number larger than that illustrated in FIG. 3B (e.g., about 300 base dies).

As illustrated in FIG. 3A, a plurality of grooves 32 radially extending from the through-hole 31 as a start point are formed in the first surface 30a of the base die 30. The plurality of grooves 32 communicate with the center through-hole 31, and gas can be introduced into the grooves 32 from the through-hole 31. The position of the end of each groove 32 in the extending direction is preferably set inward of the outer periphery of the electronic device 10 to be fixed. The device support 1 can supply gas between the second surface 10b of the electronic device 10 and the first surface 30a of the base die 30 through the through-hole 21 of the base wafer 20, the through-hole 31 of the base die 30, and each groove 32. Thus, the device support 1 can promote separation of the electronic device 10.

As illustrated in FIG. 3B, each base die 30 is bonded to the flat first surface 20a of the base wafer 20, i.e., one surface of the carrier 2 has a projecting and recessed shape. The base dies 30 are arranged in a matrix on the first surface 20a of the base wafer 20.

As illustrated in FIG. 4, a width 30w of each base die 30 may be set to an appropriate dimension in accordance with a width 10w of the electronic device 10 to be fixed to the first surface 30a. For example, when the width 10w of each electronic device 10 is 10 mm, the width 30w of each base die 30 may be set to a range of about 11 mm or more and about 15 mm or less. The width 30w of each base die 30 according to the embodiment is set to 12 mm.

Further, it is preferable to provide a clearance between the base dies next to each other. When the width 30w of each base die 30 is 12 mm as described above, a distance D1 between the centers of the base dies 30 may be, for example, set to a range of about 12 mm or more and 18 mm or less. The distance D1 according to the embodiment is set to 13 mm. Thus, the distance between the centers of the electronic devices 10 fixed to the base dies 30 is 13 mm. A distance D2 (clearance width) between the base dies 30 next to each other may be set to a range of about 0 mm or more and 3 mm or less. An interval D2 according to the embodiment is 1 mm.

As illustrated in FIGS. 2A and 2B, the second surface 10b of each electronic device 10 is fixed to the first surface 30a of each base die 30 via a second bonding layer 42. The second bonding layer 42 bonds the electronic device 10 and the base die 30 to each other with a bonding force smaller than the bonding force applied by the first bonding layer 41. The second bonding layer 42 bonds the electronic device 10 and the base die 30 by means of hydrogen bonding (bonding due to an intermolecular force), adhesion with a lowered bonding force, or the like. In the hydrogen bonding, the second surface 10b of the electronic device 10 and the first surface 30a of the base die 30 are hydrophilized, and thus the electronic device 10 and the base die 30 are bonded via respective hydrophilic groups (OH groups). The second bonding layer 42 enables each electronic device 10 to be immovably fixed on each base die 30, and to be readily separated from each base die 30 due to a separating operation.

The device support 1 according to the first embodiment is basically configured as described above. In the following, a process flow of formation and inspection of the device support 1 will be described with reference to FIG. 5. FIG. 5 is a schematic diagram illustrating a process flow of an inspection method using the device support 1.

A wafer providing step illustrated in FIG. 5 corresponds to step S103 of the inspection method according to the first embodiment illustrated in FIG. 1A. That is, the device cores fragmented in the production process are stacked on each logic die of the logic wafer, thereby providing a logic wafer 100 including the electronic devices 10 on one surface of the logic wafer 100. The device core of each electronic device 10 on the logic wafer 100 is exposed upward.

Next, the inspection method performs a wafer cleaning step of transferring the logic wafer 100 to a cleaner 300, and cleaning each electronic device 10 on the logic wafer 100. For example, the cleaner 300 includes a nozzle 301 disposed above the logic wafer 100, and can discharge a processing liquid from the nozzle 301 while rotating the logic wafer 100, thereby spreading the processing liquid over the entire surface of the logic wafer 100. Thus, the second surface 10b (device core) of each electronic device 10 is hydrophilized. As another example of hydrophilization, it is possible to transfer the wafer 100 to be inspected into a plasma space, in which plasma processing is performed.

Further, the inspection method performs a dicing step (step S104 in FIG. 1) of performing dicing each electronic device 10 of the logic wafer 100. In the dicing step, for example, a plurality of divided electronic devices 10 are placed and attached on a holding jig 200 including a dicing tape 201 and a dicing frame 202. In the production process, the order of the wafer cleaning step and the dicing step may be in reverse.

Subsequently, the inspection method performs a device bonding step (step S105 in FIG. 1A) of bonding each fragmented electronic device 10 to the carrier 2. The carrier 2 used in this device bonding step is provided in a step different from the above step.

Specifically, the inspection method performs a carrier providing step of providing the base wafer 20. The through-holes 21 formed in the base wafer 20 may be formed in advance in the base wafer 20 before the carrier providing step. Alternatively, the through-holes 21 may be formed simultaneously with the through-holes 31 after bonding of the base dies 30.

After the carrier providing step, the inspection method performs a base die bonding step of bonding each base die 30 to the first surface 20a of the base wafer 20. In the base die bonding step, the base dies 30 are arranged in a matrix at designed intervals, and are firmly fixed to the first surface 20a of the base wafer 20 due to the first bonding layer 41, thereby forming the carrier 2.

Subsequently, the inspection method performs a carrier cleaning step of transferring the carrier 2 to the cleaner 300, and cleaning the carrier 2. The cleaner 300 may be the same as or different from the device used for cleaning the wafer 100 to be inspected. Thus, the first surface 30a of each base die 30 of the carrier 2 is hydrophilized. Then, the carrier 2, which has undergone this carrier cleaning step, is used for the device bonding step.

In the device bonding step, each fragmented electronic device 10 held by the holding jig 200 is transferred to each base die 30 of the carrier 2, and each electronic device 10 is bonded to each base die 30. As described above, since the second surface 10b of the electronic device 10 is hydrophilized in the wafer cleaning step, and the first surface 30a of the base die 30 is hydrophilized in the carrier cleaning step, each electronic device 10 and each base die 30 can be bonded through hydrogen bonding. For example, the device support 1 is formed by respectively bonding the electronic devices 10 to all the base dies 30. However, the device support 1 may be in a state in which the electronic devices 10 are not bonded to some of the base dies 30.

The inspection method performs an inspecting step (step S106 in FIG. 1A) of transferring the device support 1, formed in the device bonding step, into an inspection apparatus 400, and inspecting each electronic device 10 using the inspection apparatus 400. The inspection apparatus 400 includes a probe card 401 connected to a tester (not shown). The probe card 401 includes a plurality of probes 402 projecting vertically downward. The inspection apparatus 400 performs electrical inspection of each electronic device 10 by transferring the device support 1 using a stage (not shown) and contacting each probe 402 with the electrode pad or bump of each electronic device 10 of the device support 1.

In the inspection of the device support 1, each electronic device 10 is immovably fixed to the hard carrier 2 formed of a material including at least one of silicon or carbon. Thus, the inspection apparatus 400 can stably inspect each electronic device 10, while suppressing displacement of each electronic device 10. When adjusting the temperature in the inspection, the carrier 2 reduces thermal resistance, and smoothly transmits heat to be adjusted on the stage to each electronic device 10. Therefore, the carrier 2 can increase efficiency and accuracy of the inspection of each electronic device 10. In other words, an inspection system 500 configured to inspect each electronic device 10 is formed by combining the inspection apparatus 400 and the carrier 2 according to the first embodiment.

After the inspection step in the inspection system 500, the inspection method according to the first embodiment performs a separating step (step S107 in FIG. 1A) of separating each electronic device 10 from the carrier 2. In this separating step, for example, gas (e.g., air or an inert gas) is supplied from the second surface 20b of the base wafer 20 through the through-holes 21 and 31 using a separator (not shown), thereby promoting separation of each electronic device 10 from each base die 30. In the separation of the electronic device 10, a separating pin may be inserted into the through-holes 21 and 31 to project the electronic device 10 from the base die 30.

For example, each electronic device 10 separated from each base die 30 is transferred to the dicing tape 201 of the holding jig 200. Then, each electronic device 10 held by the holding jig 200 is, for example, provided to an electronic circuit including a GPU, and mounted on the electronic circuit.

The carrier 2 after each electronic device 10 is separated in the separating step is, for example, transferred to the cleaner 300, followed by cleaning. Thus, particles and the like are removed from the carrier 2, and the first surface 30a of each base die 30 is hydrophilized. Therefore, the carrier 2 can be reused for inspection of the electronic devices 10.

As described above, the inspection method according to the first embodiment takes a form in which the fragmented electronic devices 10 are supported by the carrier 2, thereby successfully inspecting each electronic device 10 before mounting on an electronic circuit. For example, when inspection is performed on the electronic devices 10 held by the dicing tape 201 and the dicing frame 202, it is difficult to accurately position each electronic device 10 with respect to each probe 402. The carrier 2 enables accurate positioning of each electronic device 10.

The carrier 2, the inspection system 500, and the inspection method according to the present disclosure are not limited to the first embodiment, and can take various modified examples. For example, the carrier 2 is not limited to the use for inspection, and may be configured to hold each electronic device 10 for any other substrate processing. Examples of the other substrate processing include liquid processing, thermal processing, cleaning, and the like.

For example, the base wafer 20 and each base die 30 of the carrier 2 may be free from the through-holes 21 and 31, as long as the electronic device 10 can be separated from each base die 30 due to a lateral load or a vertical load. Also, the base die 30 may be free from the grooves 32, as long as the electronic device 10 can be separated using the through-holes 21 and 31.

Further, for example, the carrier 2 is not limited to a configuration in which the electronic devices 10 are supported by the base dies 30 on a one-by-one basis, and may have a configuration in which the single electronic device 10 is supported by the plurality of base dies 30. For example, the peripheral portions of the four corners of the single electronic device 10 may be supported by the four base dies 30. Further, arrangement of the base dies 30 is not limited to the arrangement in which the base dies 30 are arranged at positions spaced apart from each other across a clearance, and the base dies 30 may be arranged side by side to be in contact with each other. This can increase the number of the arranged electronic devices 10, thereby efficiently performing inspection.

The device support 1α according to a modified example illustrated in FIG. 2B is different from the device support 1 in that each electronic device 10 placed on each base die 30 is adsorbed in vacuum by stacking a closing wafer 45 on the base wafer 20 to close the through-holes 21 and 31. Specifically, the device bonding step (see FIG. 5) of bonding each electronic device 10 to each base die 30 is performed in an environment of a vacuum atmosphere. Thus, the through-holes 21 and 31 of the carrier 2 are in a vacuum atmosphere in a state in which each electronic device 10 is placed on each base die 30. In this state, when the closing wafer 45 is stacked on the second surface 20b of the base wafer 20 to close the through-holes 21 and 31, the device support 1α can adsorb each electronic device 10 in vacuum with an appropriate amount of pressure, i.e., a vacuum pressure of the through-holes 21 and 31.

Therefore, the inspecting step of the inspection method (the inspection apparatus 400) can inspect each electronic device 10 that is further reliably fixed. Further, in the separating step after the inspection, by removing the closing wafer 45 from the base wafer 20, the through-holes 21 and 31 are in an atmospheric pressure, thereby stopping the adsorption of each electronic device 10. In the separating step, gas may be supplied into the through-holes 21 and 31, opened by removing the closing wafer 45, to promote the separation of each electronic device 10. Thus, even if each electronic device 10 is firmly attached to the base die 30, each electronic device 10 can be smoothly separated.

### Second Embodiment

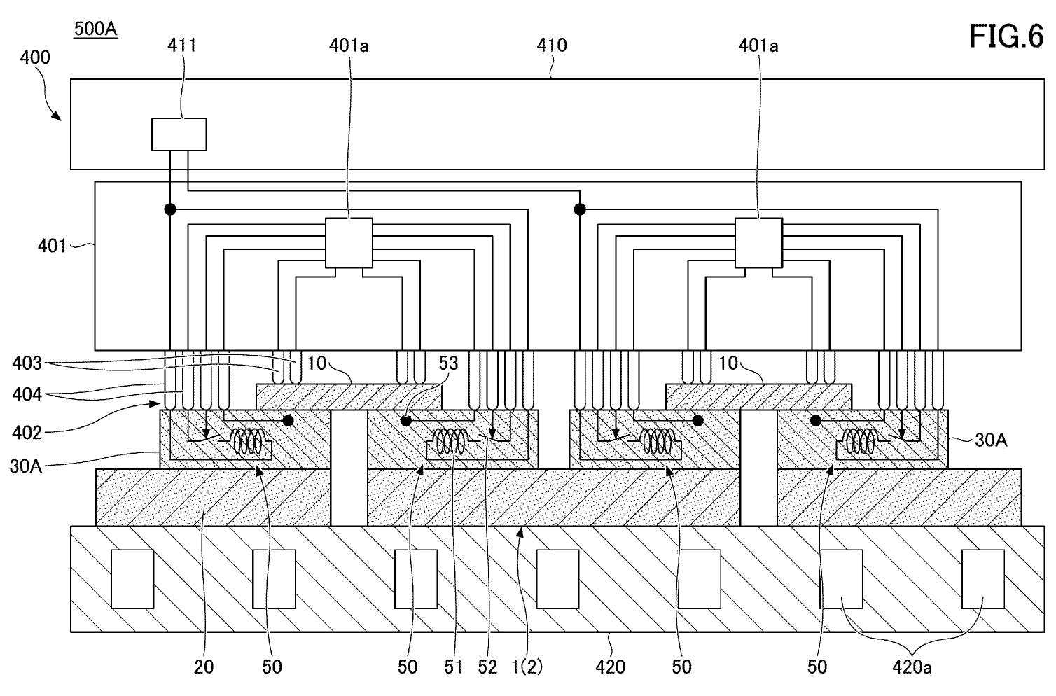

FIG. 6 is a partial cross-sectional diagram schematically illustrating an inspection state of an inspection system 500A according to a second embodiment of the present disclosure. As illustrated in FIG. 6, the inspection system 500A according to the second embodiment is different from the inspection system 500 according to the first embodiment in that the temperature of each electronic device 10 is adjustable by each base die 30A of the carrier 2. In other words, the base die 30A has a circuit that can be used for substrate processing, such as inspection or the like.

Specifically, the base die 30A includes therein a temperature adjuster 50. The temperature adjuster 50 includes a heater wire 51, a switch 52 configured to switch between supply and non-supply of power to the heater wire 51, and a temperature sensor 53 configured to detect the temperature of the electronic device 10. The heater wire 51, the switch 52, and the temperature sensor 53 are interconnected to electrode pads individually provided on the first surface 30a of the base die 30A. Each electrode pad of the base die 30A is exposed to face each probe 402 of the inspection apparatus 400 around the electronic device 10.

The inspection apparatus 400 of the inspection system 500A is configured to contact each probe 402, projecting from the probe card 401, with both of each electronic device 10 of the device support 1 and each electrode pad exposed from the base die 30A. That is, each probe 402 includes a device probe 403 configured to contact each electronic device 10, and a die probe 404 configured to contact each base die 30A.

Of a plurality of die probes 404, the die probes 404 connected to one end of the heater wire 51 are connected to a power supply module 411 provided in a tester 410 of the inspection apparatus 400. The power supply module 411 is configured to supply power for temperature adjustment to the heater wire 51. The power supply module 411 may be disposed outside the inspection apparatus 400. The die probes 404 connected to the other end of the heater wire 51, the switch 52, and the temperature sensor 53 are connected to a controller 401a disposed in the probe card 401.

At the time of inspection of the electronic device 10, the controller 401a detects the actual temperature using a temperature sensor 53, and controls on/off of the switch 52 to maintain the actual temperature at the target temperature. Thus, the base die 30A can successfully adjust the temperature of the electronic device 10 to the target temperature at a position close to the electronic device 10. The inspection apparatus 400 can adjust the temperature for each of the plurality of electronic devices 10. The controller 401a may be connected to the device probe 403 in contact with the electronic device 10, thereby controlling the inspection of the electronic device 10. The controller 401a may be disposed in the tester 410 rather than in the probe card 401.

For example, the inspection apparatus 400 includes flow paths 420a in the stage 420 configured to support the device support 1, and can allow a temperature-controlled medium to flow through the flow paths 420a, thereby adjusting the temperature of the electronic device 10. However, when using the stage 420, the stage 420 is far from each electronic device 10, and the temperature adjustment is performed through a plurality of members. Thus, the temperature adjustment of each electronic device 10 takes a significant amount of time, potentially resulting in reduction in accuracy of the temperature adjustment. The inspection system 500A, including the temperature adjuster 50 in the base die 30A on which each electronic device 10 is mounted, can perform the temperature adjustment of each electronic device 10 efficiently and accurately. The inspection system 500A may perform the temperature adjustment of each electronic device 10 using the temperature adjuster 50, while allowing the temperature-controlled medium to flow through the flow paths 420a.

### Third Embodiment

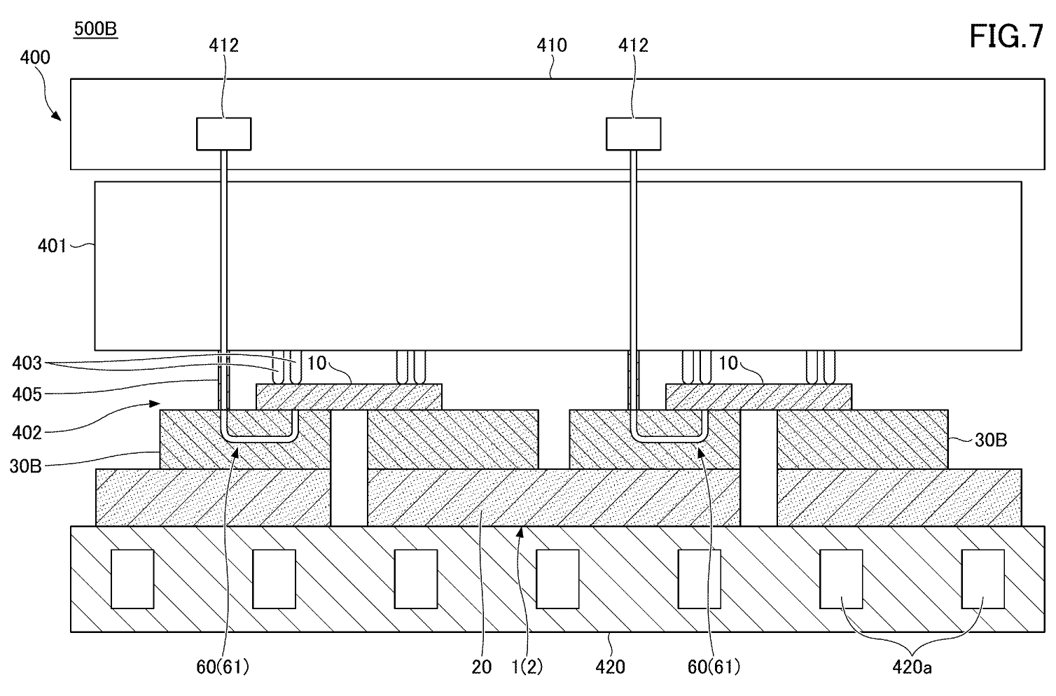

FIG. 7 is a partial cross-sectional diagram schematically illustrating an inspection state of an inspection system 500B according to a third embodiment of the present disclosure. As illustrated in FIG. 7, the inspection system 500B according to the third embodiment is different from the inspection systems 500 and 500A in that the electronic device 10 to be inspected is a silicon photonics device.

In this case, the electronic device 10 includes a light-receiving port, in the second surface 10b, configured for the silicon photonics device to receive light. Alternatively, the electronic device 10 may include a light-projecting port, in the second surface 10b, configured to project light from the silicon photonics device.

The base die 30B of the device support 1 includes a light transmitter 60 therein, configured to guide light to the light-receiving port of the electronic device 10 or guide light from the light-projecting port to the outside. The light transmitter 60 includes an optical path 61 extending from the first surface 30a of the base die 30B through the interior to another portion of the first surface 30a. An opening at one end of the optical path 61 faces the light-receiving port or the light-projecting port in the rear surface (the second surface 10b) of the electronic device 10, and an opening at the other end of the optical path 61 is provided in an exposed surface around the electronic device 10.

The inspection apparatus 400 includes the device probes 403 as the plurality of probes 402, and a light guide probe 405 connected to the optical path 61 of the base die 30B. The light guide probe 405 includes a light guide path therein, configured to allow light to pass through the light guide path without attenuating the light. The light guide probe 405 is connected to a light emitter 412 (or a light receiver) provided inside the tester 410 through a light guide path provided in the probe card 401.

For example, the light emitter 412 is configured to allow light incident on the light-receiving port of the electronic device 10 through the optical path 61 of the light guide probe 405 and the base die 30B. The inspection apparatus 400 can inspect the electronic device 10, i.e., a silicon photonics device, by receiving a signal generated at the time of light being incident on the electronic device 10 in the probe card 401 and the tester 410. Alternatively, the light receiver is configured to receive light emitted from the light-projecting port of the electronic device 10 through the optical path 61 of the light guide probe 405 and the base die 30B. The inspection apparatus 400 can inspect the electronic device 10, i.e., a silicon photonics device, by transmitting an electrical signal to the electronic device 10, and receiving light, emitted from the electronic device 10, by the light receiver.

### Fourth Embodiment

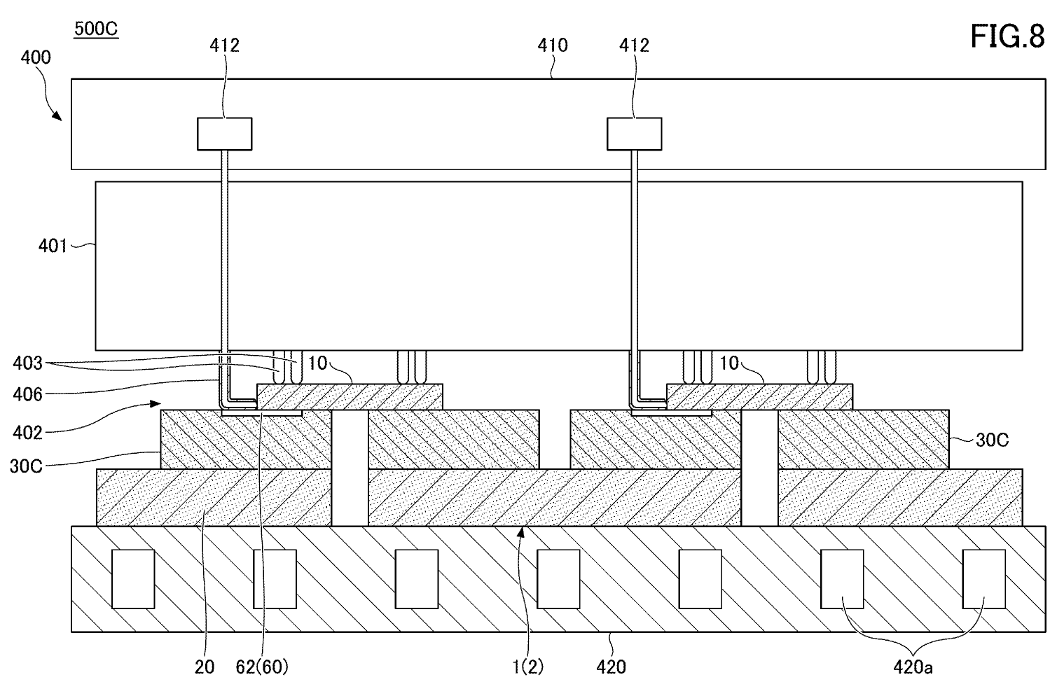

FIG. 8 is a partial cross-sectional diagram schematically illustrating an inspection state of an inspection system 500C according to a fourth embodiment of the present disclosure. As illustrated in FIG. 8, the inspection system 500C according to the fourth embodiment also uses a silicon photonics device as the electronic device 10 to be inspected. However, the inspection system 500C is different from the third embodiment in that light can be input from or output to the electronic device 10 from a lateral direction.

Specifically, the probe 402 of the inspection apparatus 400 includes a light guide probe 406 projecting from the probe card 401, bending at a position partway through the light guide probe 406, and extending laterally. The light guide probe 406 is configured to allow light to pass through the light guide probe 406 without attenuating the light at this bent portion. The tip of the light guide probe 406 contacts the second bonding layer 42 between the second surface 10b of the electronic device 10, and the first surface 30a of the base die 30C. Instead of or along with the bent portion, the light guide probe 406 may be configured to transmit light between the second surface 10b and the first surface 30a (the second bonding layer 42) using a grating coupler or the like. For example, the grating coupler is formed as a diffraction grating element configured to efficiently enter/exit or couple light in a waveguide in the light guide probe 406, and is connected at an appropriate angle between the tip of the light guide probe 406 and a portion between the second surface 10b and the first surface 30a. In this case, the light guide probe 406 can refract light and guide light to the electronic device 10.

A light guide groove 62 (optical path) configured to guide light from the light guide probe 406 may be formed in the first surface 30a of the base die 30C. The light guide groove 62 is configured to transmit light to the light-receiving port or the light-projecting port of the electronic device 10 from a lateral side of the electronic device 10, for example, when the light guide probe 406 is disposed and the tip of the light guide probe 406 contacts the second bonding layer 42. Therefore, the inspection system 500C can successfully inspect the electronic device 10, i.e., a silicon photonics device.

### Fifth Embodiment

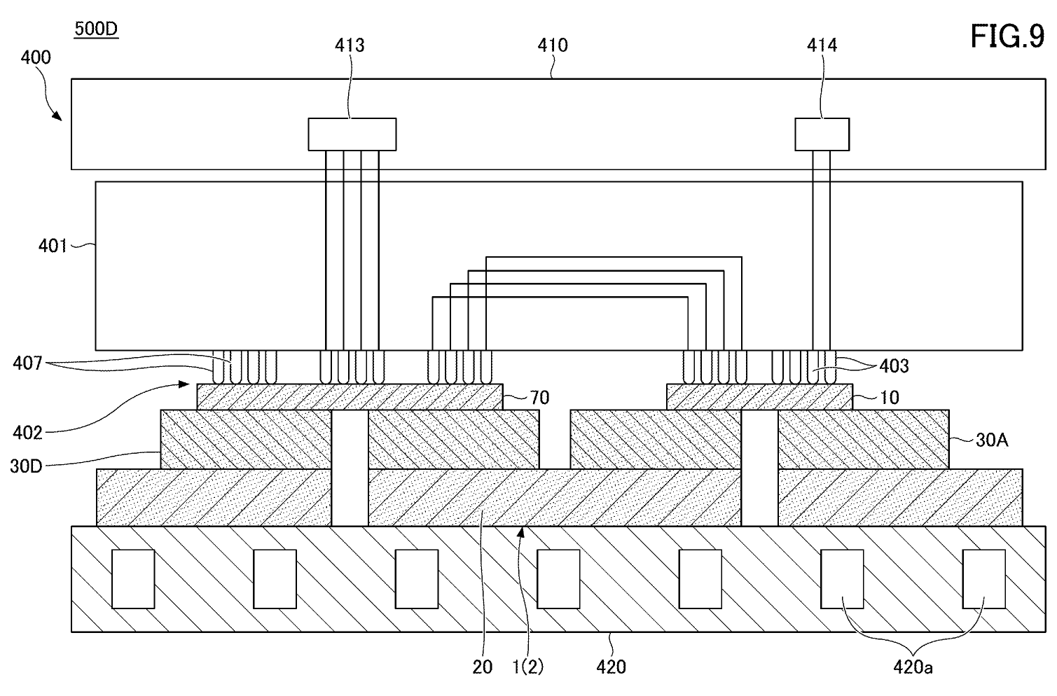

FIG. 9 is a partial cross-sectional diagram schematically illustrating an inspection state of an inspection system 500D according to a fifth embodiment of the present disclosure. The inspection system 500D according to the fifth embodiment is different from the inspection systems 500 and 500A to 500C in that a reference device 70 of a device (e.g., a high-end processor, such as a GPU or the like) to be assembled to the electronic device 10 is mounted on the device support 1. The inspection system 500D is configured to transmit and receive a signal between the reference device 70 and each electronic device 10.

Specifically, the reference device 70 is an actually assembled device that is fixed to the base wafer 20 and can normally input and output a signal. Also, the reference device 70 is positionally adjusted such that each electrode pad faces each probe 402 of the inspection apparatus 400. Although FIG. 9 illustrates an example in which the reference device 70 is bonded to a base die 30D for the reference device 70, the reference device 70 may be directly fixed to the base wafer 20 without the base die 30D.

The probe card 401 of the inspection apparatus 400 includes a plurality of device probes 403 and a plurality of reference device probes 407 contacting each electrode pad of the reference device 70. Some of the device probes 403 are connected to a power supply module 414 in the tester 410. Some of the reference device probes 407 are connected to a remote controller 413 in the tester 410. The remote controller 413 is configured to supply driving power to the reference device 70, and has the function of outputting a drive command or the like for the reference device 70.

The device probes 403 and the reference device probes 407 are connected to each other in the probe card 401. Thus, for example, a signal output from the reference device 70 through the reference device probe 407 is transmitted to the electronic device 10 through the probe card 401 and the device probe 403, and the behaviors of the electronic device 10 at this time can be confirmed.

In this manner, the inspection system 500D inspects the electronic device 10 using the reference device 70 the same as the actually assembled device, thereby confirming in advance a combination failure between the actually assembled device and the electronic device 10. Thus, when the electronic device 10 is mounted on an electronic circuit including the device, it is possible to eliminate the electronic device 10 exhibiting the combination failure, and assemble the electronic device 10 having no abnormality.

### Sixth Embodiment

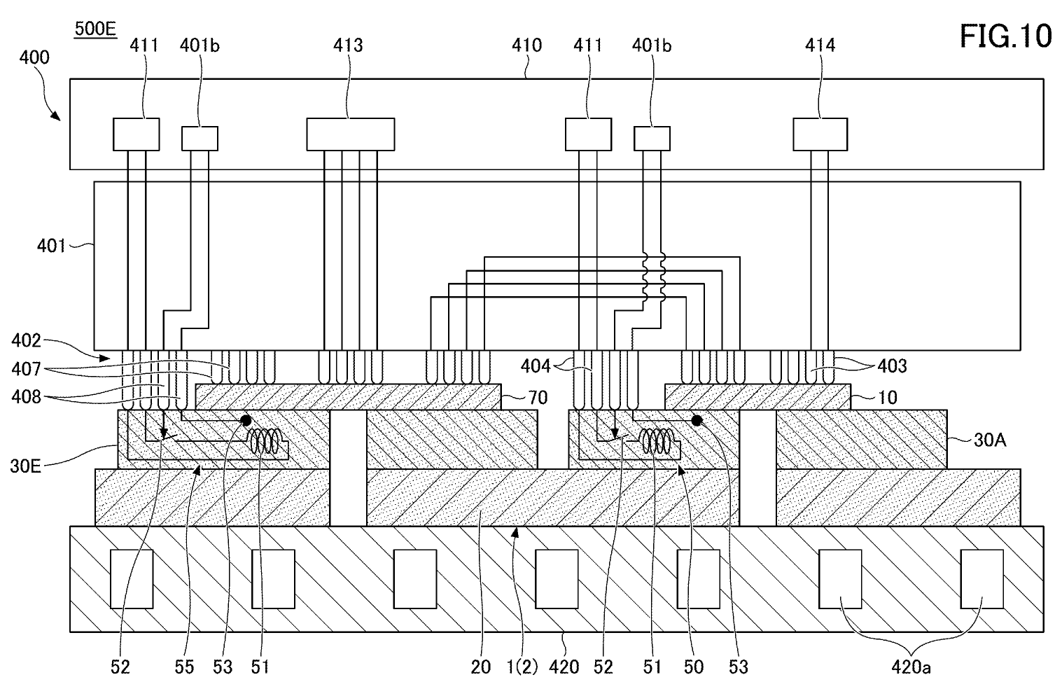

FIG. 10 is a partial cross-sectional diagram schematically illustrating an inspection state of an inspection system 500E according to a sixth embodiment of the present disclosure. The inspection system 500E according to the sixth embodiment is different from the inspection systems 500 and 500A to 500D in that, as in the fifth embodiment, the inspection system 500E transmits and receives a signal between each electronic device 10 and the reference device 70 of the device support 1, and includes temperature adjusters 50 and 55.

In this case, as in the first embodiment, the temperature adjuster 50 is configured by disposing the heater wire 51, the switch 52, and the temperature sensor 53 in the base die 30A, and configured to adjust the temperature of each electronic device 10. The temperature adjuster 55 is provided in the base die 30E for the reference device 70, and is configured to adjust the temperature of the reference device 70. As in the temperature adjuster 50, the temperature adjuster 55 includes the heater wire 51, the switch 52, and the temperature sensor 53. The reference device 70 according to the embodiment may be configured to be separably fixed to the base die 30E. In this case, the reference device 70 may be a device (GPU) actually mounted in an electronic circuit along with the electronic device 10. In the sixth embodiment, the electronic device 10 and the device actually mounted in the electronic circuit can be temporarily connected in the inspection system 500E, thereby inspecting a combination failure or the like. Thus, after completion of the inspection, both the device and the electronic device 10 can be separated from the carrier 2 and mounted on the same electronic circuit, thereby further reliably driving the electronic circuit.

Each probe 402 of the inspection apparatus 400 includes the device probe 403, the die probe 404, the reference device probe 407, and a die probe 408. The die probe 408 is connected to the interconnects of the heater wire 51, the switch 52, and the temperature sensor 53 of the temperature adjuster 50. The die probe 408 is connected to a controller 401b provided in the tester 410. The temperature adjuster 55 is configured to adjust the temperature of the reference device 70 in accordance with control of the controller 401b.

The inspection system 500E can perform inspection in which both the temperature of the electronic device 10 and the temperature of the reference device 70 are adjusted. Thus, the inspection system 500E can confirm in advance a combination failure of the device and the electronic device 10 while changing the temperature.

### Seventh Embodiment

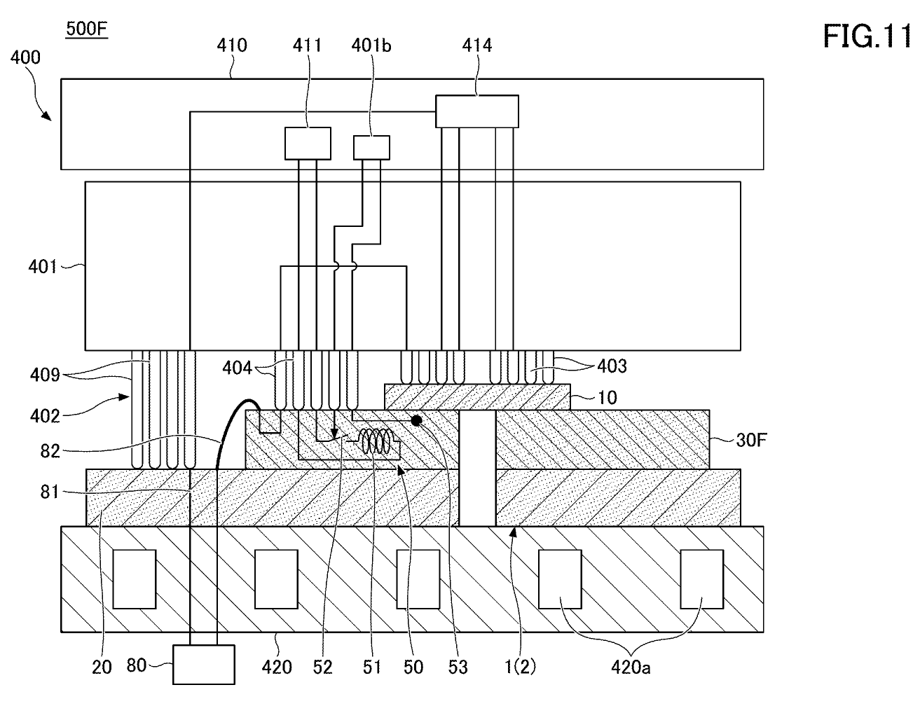

FIG. 11 is a partial cross-sectional diagram schematically illustrating an inspection state of an inspection system 500F according to a seventh embodiment of the present disclosure. The inspection system 500F according to the seventh embodiment is different from the inspection systems 500 and 500A to 500E in that the inspection system 500F has the function of obtaining log information at the time of inspection of the electronic device 10.

Specifically, the inspection system 500F includes a log recorder 80 configured to store information of the tester 410, information of the electronic device 10, information of the sensor disposed in the base die 30F, and the like. The probe 402 of the inspection apparatus 400 includes the device probe 403, the die probe 404, and a carrier probe 409 configured to contact the base wafer 20.

The carrier probe 409 is connected to the power supply module 414 of the tester 410, and connected to the log recorder 80 through an interconnect 81 in the base wafer 20 contacted by the carrier probe 409. The base wafer 20 and the base die 30F are connected to each other through a bonding wire 82 to enable information communication. The die probe 404 for the die to which the bonding wire 82 is connected may be connected to the electronic device 10, for example, through the interconnect in the probe card 401 and the device probe 403. Thus, the log recorder 80 can obtain information of the electronic device 10 through the base die 30F and the base wafer 20.

FIG. 11 illustrates an example in which an I/F connection port electrically connected to the interconnect 81 in the base wafer 20 is provided in the stage 420, and the device support 1 is connected to the log recorder 80 provided in a prober (not shown) through the interior of the stage 420. However, the connection between the device support 1 and the log recorder 80 is not limited to this, and may take various forms. For example, the log recorder 80 may be directly connected to the base wafer 20 to transmit data. No particular limitation is imposed on the method of transmitting data to the log recorder 80, and I2C communication, CAN communication, or the like may be used.

Examples of the log information read by the log recorder 80 include inspection information of the electronic device 10, temperature information, an operation rate of the heater wire 51 of the temperature adjuster 50, and information of power (e.g., current or voltage) sensed by the power supply module 414 or the probe card 401. By storing various types of log information during the inspection in the log recorder 80, it is possible to recognize the state of the electronic device 10 or the state of the base die 30. Thus, it is possible to know appropriate timings of maintenance, replacement, and the like of the carrier 2.

### Eighth Embodiment

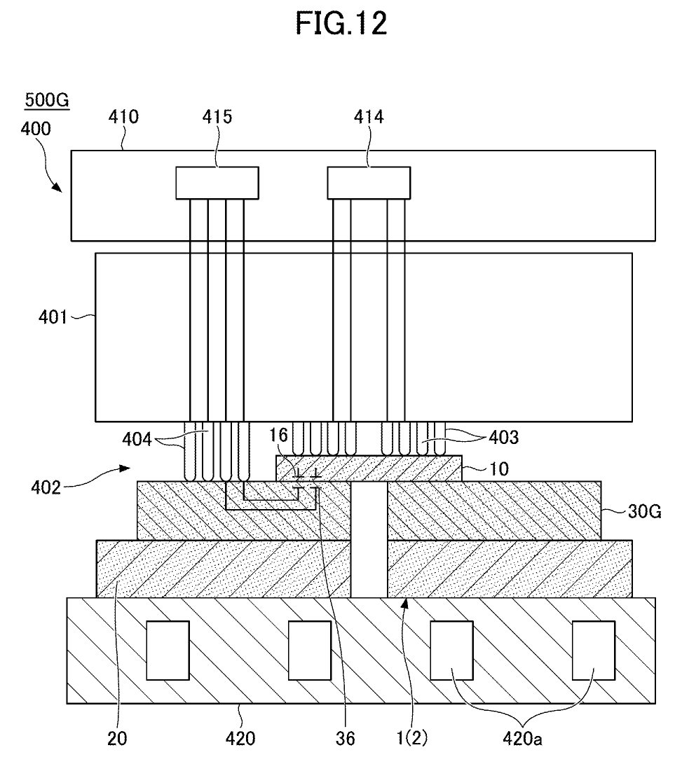

FIG. 12 is a partial cross-sectional diagram schematically illustrating an inspection state of an inspection system 500G according to an eighth embodiment of the present disclosure. The inspection system 500G according to the eighth embodiment is different from the inspection systems 500 and 500A to 500F in that the inspection system 500G is configured to perform non-contact communication and/or non-contact power supply between the electronic device 10 and the base die 30. FIG. 12 illustrates a structure in which non-contact communication is performed between the electronic device 10 and the base die 30.

In this case, a communication antenna module 36 for non-contact communication is provided inside the base die 30G and at a position close to the first surface 30a. For example, the communication antenna module 36 is disposed to face a communication antenna module 16 provided in the electronic device 10, and is configured to perform short-range wireless communication. The communication antenna modules 16 and 36 need not be disposed at positions facing each other, as long as the communication antenna modules 16 and 36 can perform short-range wireless communication. The communication antenna module 36 is connected to the electrode pad provided on the first surface 30a of the base die 30G through an interconnect passing through the base die 30G.

The die probe 404 of the inspection apparatus 400 is connected to the electrode pad of the base die 30G, and connected to a communication information processor 415 provided in the tester 410. Thus, the inspection apparatus 400 can readily obtain information transmitted from the communication antenna module 16 of the electronic device 10 through the die probe 404 and the communication antenna module 36 of the base die 30G. In particular, cleanliness is important for bonding between the electronic device 10 and the base die 30. The non-contact communication can increase cleanliness.

FIG. 12 illustrates a configuration in which power of the power supply module 411 is supplied to the electronic device 10 through the device probe 403. However, the inspection system 500G can perform non-contact power supply to the electronic device 10 by disposing a power supply antenna module similar to the communication antenna modules 16 and 36.

### Ninth Embodiment

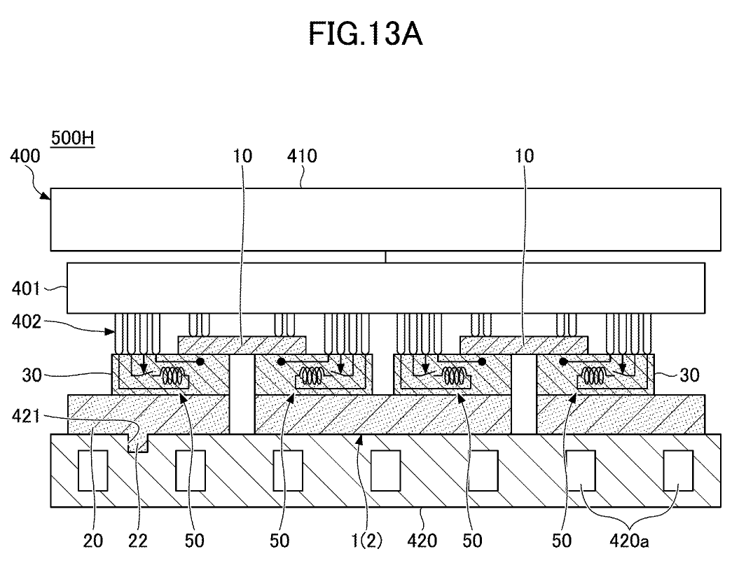

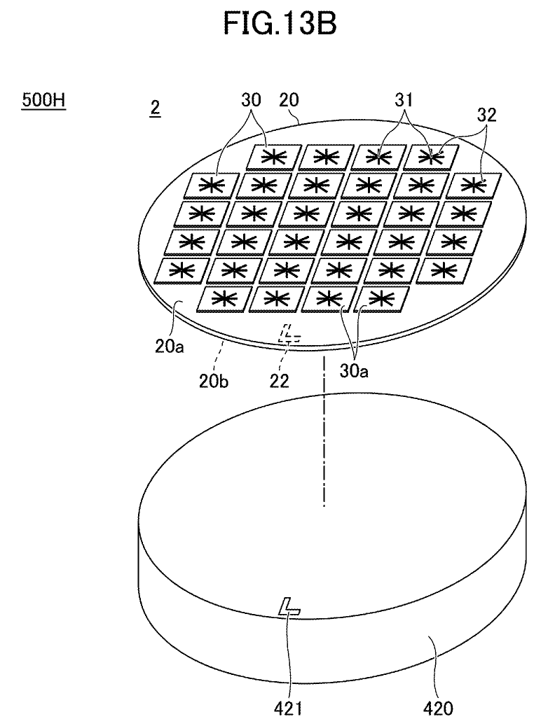

FIG. 13A is a partial cross-sectional diagram schematically illustrating an inspection state of an inspection system 500H according to a ninth embodiment of the present disclosure. FIG. 13B is a perspective diagram illustrating positioning of the carrier 2 and the stage 420. The inspection system 500H according to the ninth embodiment is different from the inspection systems 500 and 500A to 500G in that the inspection system 500H includes a positioning structure configured to position the carrier 2 and the stage 420 when the base wafer 20 of the carrier 2 is to be placed on the stage 420.

The positioning structure is, for example, an engageable projection and recess formed in the second surface 20b of the base wafer 20 and in the top surface of the stage 420. In FIGS. 13A and 13B, a projection 22 is formed in the base wafer 20, while a recess 421 is formed in the stage 420. The number of positioning structures (the projection 22 and the recess 421) is not limited to one, and a plurality of positioning structures may be provided. Also, a recess may be formed in the base wafer 20, while a projection may be formed in the stage 420. When a plurality of positioning structures are formed, a recess and a projection may be formed in the stage 420, while a projection and a recess may be formed in the base wafer 20 at positions corresponding to the recess and the projection formed in the stage 420.

The projection 22 is, for example, formed in an L shape in a plan view, and projects downward from the second surface 20b. The projection 22 may be a projection cut out from a silicon wafer. In this case, the projection 22 may be bonded to the base wafer 20 using a bonding technique, such as fusion bonding or the like. Alternatively, the projection 22 may be bonded to the base wafer 20 using an adhesive. The shape of the projection 22 is not limited to the L shape, and may be a triangle, a circle, a cross, or any other shape. The same applies to the recess 421.

By using the positioning structure in this manner, i.e., inserting the projection 22 of the base wafer 20 into the recess 421 of the stage 420, it is possible to readily position the base wafer 20. As a result, the inspection system 500H enables each probe 402 to further accurately contact each electronic device 10 and each base die 30 over the base wafer 20.

### Modified Example

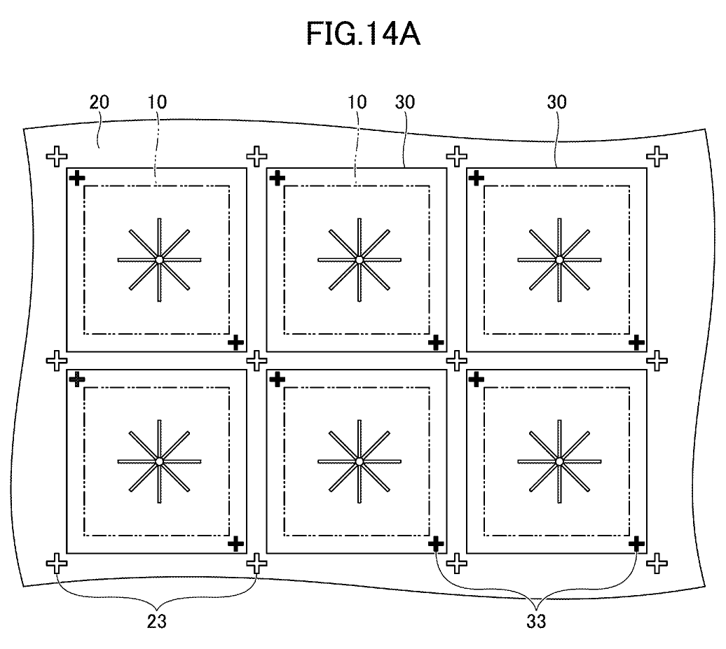

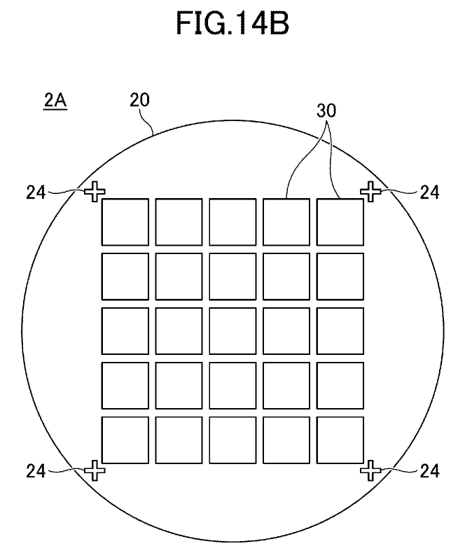

FIG. 14A is a plan diagram illustrating a portion of the base wafer 20 and each base die 30 according to a modified example. FIG. 14B is a plan diagram illustrating the base wafer 20 according to the modified example. As in the modified example illustrated in FIGS. 14A and 14B, a carrier 2A may include one or more alignment marks for increasing the positional accuracy in the arrangement of the electronic devices 10, the base dies 30, and the like. That is, when the probes 402 of the probe card 401 are collectively contacted with the fragmented electronic devices 10 and the base dies 30, the electronic devices 10 and the base dies 30 need to be fixed with an appropriate positional accuracy (an error with respect to a reference position is ± 1 micrometer (μm)).

Therefore, the carrier 2A can increase the positional accuracy at the time of fixing by attaching alignment marks to the base wafer 20 and the base dies 30. The alignment marks are printed using a laser, photolithography, or the like. Examples of the alignment marks include, for example, a plurality of carrier local alignment marks 23 printed near each base die 30 on the base wafer 20, and a plurality of base die local alignment marks 33 printed on each base die 30. Alternatively, the alignment marks may be printed as global alignment marks 24 indicating the position of the entirety of the plurality of base dies 30 on the base wafer 20. Some of the carrier local alignment marks 23 may be used as the carrier global alignment marks 24. The sizes, shapes, numbers, and the like of these various alignment marks may be defined as desired in accordance with an alignment mechanism, the magnification of a camera lens, a space provided, and the required accuracy.

The carrier global alignment marks 24 are rough adjustment marks configured to find each carrier local alignment mark 23. Also, the carrier local alignment marks 23 are used as a position target mark at the time of mounting of each base die 30. Further, the base die local alignment marks 33 are marks for confirming the positional relationship with the carrier local alignment marks 23 at the time of bonding each base die 30 to the base wafer 20. For example, a transfer device configured to individually transfer and bond each base die 30 to the base wafer 20 recognizes the positional relationship of the base die local alignment marks 33 with respect to the carrier local alignment marks 23. FIG. 14A illustrates an example in which the base dies 30 are individually bonded such that each base die local alignment mark 33 is disposed at a position of 45 degrees (°) with respect to each carrier local alignment mark 23, which is a symbol of +. For example, the base die local alignment marks 33 are also used to recognize the positional relationship of the electronic devices 10 with respect to the base dies 30. As an example, the electronic devices 10 are positioned and bonded such that the corners of each electronic device 10 are disposed at a position of 45° with respect to each base die local alignment mark 33.

By using the alignment marks in this manner, it is possible to accurately position each electronic device 10 and each base die 30. Thus, the inspection system enables each probe 402 to further accurately contact each electronic device 10 and each base die 30 over the base wafer 20.

### Clauses

The technical ideas and effects of the present disclosure described in the above embodiments will be described below.

A first aspect of the present disclosure is the carrier 2 configured to collectively support the plurality of electronic devices 10 that are divided. The carrier 2 includes: the base having the flat-plate shape (the base wafer 20); and the plurality of base dies that are disposed on one surface of the base and to which the plurality of electronic devices 10 are to be separably fixed. The base and the plurality of base dies 30 include the material including at least one of silicon or carbon.

With this configuration, the carrier 2 can stably fix the plurality of divided electronic devices 10 by the base (the base wafer 20) and the plurality of base dies 30 including a material including at least one of silicon or carbon. Thus, for example, when inspecting the plurality of electronic devices 10, the plurality of probes 402 can be accurately contacted with the plurality of electronic devices 10 supported by the carrier 2, thereby appropriately performing inspection. Moreover, the base and each base die 30 including the material including at least one of silicon or carbon can smoothly transmit heat to each electronic device 10, thereby efficiently heating each electronic device 10 or removing heat from each electronic device 10.

Further, the base (the base wafer 20) and the plurality of base dies 30 include the through-holes 21 and 31 communicable with the rear surfaces of the plurality of electronic devices 10 to be fixed to the plurality of base dies 30. With this configuration, the carrier 2 can promote separation of each electronic device 10 from each base die 30 by supplying gas to the rear surface of each electronic device 10 through the through-holes 21 and 31.

Further, the plurality of base dies 30 include the grooves 32 communicating with the through-holes 31, and the grooves 32 are formed in the surfaces of the plurality of base dies 30 to which the plurality of electronic devices 10 are to be fixed. With this configuration, the carrier 2 can further promote separation of each electronic device 10 by allowing the gas supplied through the through-holes 21 and 31 to flow into the grooves 32.

Further, the closing member (the closing wafer 45) configured to close the through-holes 21 and 31 having a vacuum atmosphere is stacked on the other surface of the base (the base wafer 20) opposite to the one surface of the base. With this configuration, the carrier 2 can adsorb and fix each electronic device 10 in vacuum, using the through-holes 21 and 31 having a vacuum atmosphere, while removing the closing member to release the vacuum atmosphere, thereby separating each electronic device 10.

Further, the plurality of base dies 30 are configured to fix the plurality of electronic devices 10 to the plurality of base dies 30 on a one-by-one basis. With this configuration, the carrier 2 can firmly fix the electronic device 10 for each of the plurality of base dies 30, thereby stably performing inspection or the like.

Further, the plurality of base dies 30 are arranged in a matrix on the one surface of the base, and a clearance is provided between base dies that are next to each other among the plurality of base dies 30. With this configuration, the carrier 2 can fix the electronic devices 10 at intervals, and it is possible to perform inspection or the like while suppressing the influence of heat between the electronic devices 10.

Further, the base (the base wafer 20) and each of the plurality of base dies 30 are members different from each other, and are fixed to each other via the first bonding layer 41. The plurality of base dies 30 and the plurality of electronic devices 10 are fixed to each other via the second bonding layer 42. The bonding force of the second bonding layer 42 is smaller than the bonding force of the first bonding layer 41. With this configuration, the carrier 2 can separably fix each electronic device 10, while firmly integrating the base and each base die 30 with each other.

Further, each of the plurality of base dies 30 includes therein the temperature adjuster 50 configured to adjust the temperature of each of the fixed electronic devices 10. With this configuration, the temperature adjuster 50 enables the carrier 2 to adjust the temperature of the electronic device 10 at a position close to the electronic device 10. For example, it is possible to readily perform the temperature adjustment of the electronic device 10 during inspection.

Further, each of the plurality of base dies 30 includes therein the optical path 61 configured to transmit light between each of the plurality of base dies 30 and each of the fixed electronic devices 10. With this configuration, the carrier 2 can guide light to the electronic device 10, i.e., a photonics device, through the optical path 61 of each base die 30.

Further, the base (the base wafer 20) or the plurality of base dies 30 include the device to which each of the plurality of electronic devices 10 is to be assembled, or the base (the base wafer 20) or the plurality of base dies 30 include the reference device 70 having the function that is the same as the function of the device to which each of the plurality of electronic devices is to be assembled. With this configuration, the carrier 2 can confirm a combination failure or the like with the device to which the electronic device 10 is actually assembled.

Further, the base (the base wafer 20) and the plurality of base dies 30 include the interconnect 81 that is configured to, in response to contact with the probe 402 of the inspection apparatus 400, be electrically connected to the probe 402. With this configuration, the carrier 2 can perform various processing on each electronic device 10 through the interior of the base and each base die 30.

Further, each of the plurality of base dies 30 includes the antenna (the communication antenna module 36) that is configured to communicate with or supply power to each of the fixed electronic devices 10 in a non-contact manner. With this configuration, the carrier 2 can increase cleanliness by suppressing formation of particles or the like at a fixed site between each base die 30 and each electronic device 10. This can further stably fix each electronic device 10.

A second aspect of the present disclosure is the inspection systems 500 and 500A to 500H configured to inspect the plurality of electronic devices 10. Each of the inspection systems 500 and 500A to 500H includes: the carrier 2 configured to collectively support the plurality of electronic devices 10 that are divided; and the probe card 401 including the plurality of probes 402 configured to contact the plurality of electronic devices 10 supported by the carrier 2. The carrier 2 includes the base having the flat-plate shape (the base wafer 20), and the plurality of base dies 30 that are disposed on one surface of the base and to which the plurality of electronic devices 10 are to be separably fixed. The base and the plurality of base dies 30 include the material including at least one of silicon or carbon. In this case, the carrier 2 included in each of the inspection systems 500 and 500A to 500H can stably fix the plurality of divided electronic devices 10, thereby performing appropriate inspection of each electronic device 10.

Further, each of the plurality of probes 402 includes the device probe 403 configured to contact each of the plurality of electronic devices 10, and the die probe 404 configured to contact each of the plurality of base dies 30. With this configuration, each of the inspection systems 500 and 500A to 500H can access the base die 30 through the die probe 404, thereby performing various processing.

Further, the device probe 403 configured to contact each of the plurality of electronic devices 10 is different in height from the die probe 404 configured to contact each of the plurality of base dies 30. With this configuration, each of the inspection systems 500 and 500A to 500H can stably contact each probe 402 with each electrode pad, while appropriately dispersing the pressure at the time of contact with each probe 402.

A third aspect of the present disclosure is an inspection method of inspecting the plurality of electronic devices 10 in the carrier 2 configured to collectively support the plurality of electronic devices 10 that are divided. The inspection method includes: fixing the plurality of electronic devices 10 to the plurality of base dies 30; and contacting the plurality of probes 402 of the probe card 401 with the plurality of electronic devices 10 supported by the carrier 2, thereby inspecting the plurality of electronic devices 10. The carrier 2 includes the base having the flat-plate shape (the base wafer 20), and the plurality of base dies 30 that are disposed on one surface of the base and to which the plurality of electronic devices 10 are to be separably fixed. The base and the plurality of base dies 30 include the material including at least one of silicon or carbon.

In this case, the carrier 2 in the inspection method can stably fix the plurality of divided electronic devices 10, thereby performing appropriate inspection of each electronic device 10.

The carrier 2, the inspection systems 500 and 500A to 500H, and the inspection method according to the embodiments disclosed herein are exemplary and non-limiting in all respects. The embodiments can be modified and improved in various ways without departing from the scope and intent of claims recited. The matters described in the embodiments can take other configurations unless there is a contradiction, and can be combined unless there is a contradiction.

According to an aspect of the present disclosure, it is possible to stably fix a plurality of divided electronic devices.

What is claimed is:

1. A carrier configured to collectively support a plurality of electronic devices that are divided, the carrier comprising:
a base having a flat-plate shape; and
a plurality of base dies that are disposed on one surface of the base and to which the plurality of electronic devices are to be separably fixed, wherein
the base and the plurality of base dies include a material including at least one of silicon or carbon.

2. The carrier according to claim 1, wherein
the base and the plurality of base dies include through-holes that are communicable with rear surfaces of the plurality of electronic devices to be fixed to the plurality of base dies.

3. The carrier according to claim 2, wherein
the plurality of base dies include grooves communicating with the through-holes, and the grooves are formed in surfaces of the plurality of base dies to which the plurality of electronic devices are to be fixed.

4. The carrier according to claim 2, wherein
a closing member configured to close the through-holes having a vacuum atmosphere is stacked on another surface of the base opposite to the one surface of the base.

5. The carrier according to claim 1, wherein
the plurality of base dies are configured to fix the plurality of electronic devices to the plurality of base dies on a one-by-one basis.

6. The carrier according to claim 1, wherein
the plurality of base dies are arranged in a matrix on the one surface of the base, and
a clearance is provided between base dies that are next to each other among the plurality of base dies.

7. The carrier according to claim 1, wherein
the base and each of the plurality of base dies are members different from each other, and are fixed to each other via a first bonding layer,
the plurality of base dies and the plurality of electronic devices are fixed to each other via a second bonding layer, and
a bonding force of the second bonding layer is smaller than a bonding force of the first bonding layer.

8. The carrier according to claim 1, wherein
each of the plurality of base dies includes therein a temperature adjuster configured to adjust a temperature of each of the fixed electronic devices.

9. The carrier according to claim 1, wherein
each of the plurality of base dies includes therein an optical path configured to transmit light between each of the plurality of base dies and each of the fixed electronic devices.

10. The carrier according to claim 1, wherein
the base or the plurality of base dies include a device to which each of the plurality of electronic devices is to be assembled, or
the base or the plurality of base dies include a reference device having a function that is the same as a function of the device to which each of the plurality of electronic devices is to be assembled.

11. The carrier according to claim 1, wherein
the base and the plurality of base dies include an interconnect that is configured to, in response to contact with a probe of an inspection apparatus, be electrically connected to the probe.

12. The carrier according to claim 1, wherein
each of the plurality of base dies includes an antenna that is configured to communicate with or supply power to each of the fixed electronic devices in a non-contact manner.

13. An inspection system configured to inspect a plurality of electronic devices, the inspection system comprising:
a carrier configured to collectively support the plurality of electronic devices that are divided, and
a probe card including a plurality of probes configured to contact the plurality of electronic devices supported by the carrier, wherein
the carrier includes
a base having a flat-plate shape, and
a plurality of base dies that are disposed on one surface of the base and to which the plurality of electronic devices are to be separably fixed, and
the base and the plurality of base dies include a material including at least one of silicon or carbon.

14. The inspection system according to claim 13, wherein
each of the plurality of probes includes a device probe configured to contact each of the plurality of electronic devices, and a die probe configured to contact each of the plurality of base dies.

15. The inspection system according to claim 13, wherein
the device probe configured to contact each of the plurality of electronic devices is different in height from the die probe configured to contact each of the plurality of base dies.

16. An inspection method of inspecting a plurality of electronic devices in a carrier configured to collectively support the plurality of electronic devices that are divided, the inspection method comprising:
fixing the plurality of electronic devices to a plurality of base dies, and
contacting a plurality of probes of a probe card with the plurality of electronic devices supported by the carrier, thereby inspecting the plurality of electronic devices, wherein
the carrier includes
a base having a flat-plate shape, and
the plurality of base dies that are disposed on one surface of the base and to which the plurality of electronic devices are to be separably fixed, and
the base and the plurality of base dies include a material including at least one of silicon or carbon.
